(19) United States
(12) Patent Application Publication
(10) Pub. No.: US 2008/0173402 A1
(43) Pub. Date: Jul. 24, 2008

(54) MICROWAVE PLASMA PROCESSING APPARATUS

(75) Inventors: Nobumasa Suzuki, Yokohama-shi (JP); Yusuke Fukuchi, Atsugi-shi (JP); Yuu Nishimura, Suntou-gun (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/969,544

(22) Filed: Jan. 4, 2008

(30) Foreign Application Priority Data
Jan. 23, 2007 (JP) 2007-012902

(51) Int. Cl. C23C 16/513; B01J 19/12; H01L 21/306

(52) U.S. Cl. 156/345.41; 422/186.05; 118/723 AN; 118/723 MW

(57) ABSTRACT

A radiofrequency wave electrode that is electrically insulated from a microwave introduction portion is provided, or the microwave introduction portion also functions as a radiofrequency wave electrode, and a radiofrequency wave is superimposed on a microwave for generating plasma. With this feature a plasma having an enhanced intensity is generated even in a portion where otherwise the microwave plasma intensity may be low and reaction product may easily adhere to.

### BACKGROUND OF THE INVENTION

1. Field of the Invention

The present invention relates to a microwave plasma processing apparatus. More particularly, the present invention relates to a microwave plasma processing apparatus in which particle generation that may cause device defects is reduced and improvement in the degree of uniformity of plasma is achieved.

2. Description of the Related Art

In recent years, to meet the demand for decreasing temperature in the manufacturing process of various electronic devices, the importance of plasma processing technologies has been increasing more than ever. In particular, microwave plasma that uses a microwave (or an electromagnetic wave having a frequency higher than radiofrequency waves) as an excitation source can provide a plasma having a high density as high as or higher than 10¹² cm⁻³ and a low electron temperature as low as or lower than 1 eV. For this reason, the microwave plasma enables processing with low damage, high quality and high speed, and as a plasma, it is expected to be further developed in the future. Microwave plasma processing apparatuses are in practical use in processings such as CVD, etching, ashing, nitriding, oxidizing and cleaning.

In the plasma processing apparatus that uses a microwave as an excitation source for a processing gas, electrons can be accelerated by an electric field having a high frequency, and gas molecules can be excited, ionized and decomposed efficiently. Accordingly, the microwave plasma has high efficiency in exciting, ionizing and decomposing a gas, and it can form a high density plasma relatively easily. Therefore, the microwave plasma has the advantage of enabling processing at low temperature and high speed. In addition, the microwave plasma further has the advantage of enabling processing with low damage and high quality, since generation of plasma with a high density higher than a cutoff density prevents the microwave electric field from permeating into the bulk plasma and makes the electron temperature low. Furthermore, since the microwave has the property of permeating dielectrics, the plasma processing apparatus can be constructed as an electrodeless discharge type apparatus, which enables clean plasma processing in which metal pollution is low.

As an example of the microwave plasma processing apparatus, there has been developed an apparatus in which a circular waveguide without termination (endless circular waveguide) having a plurality of slots formed on a H-plane is used as an apparatus that introduces a microwave uniformly and efficiently. FIG. 5 is a schematic diagram of such a microwave plasma processing apparatus, and FIGS. 6A and 6B illustrate the mechanism of plasma generation in this apparatus.

Plasma processing is performed in the following manner. A substrate to be processed 502 is set on a support member 503. The interior of the plasma processing chamber 501 is evacuated through an evacuation system (not shown). Then, processing gas is introduced into the interior of the plasma processing chamber 501 at a predetermined flow rate through a gas introduction portion 505 provided in the vicinity of the plasma processing chamber 501. Then, a conductance valve (not shown) provided in the evacuation system (not shown) is adjusted to keep the interior of the plasma processing chamber 501 at a predetermined pressure. A desired electric power is supplied into the plasma processing chamber 501 from a microwave power source (not shown) through a circular waveguide without termination 508. In this process, the microwave introduced into the circular waveguide without termination 508 is divided at an E-branch portion in the introduction portion into left and right portions, which interfere with each other in the circular waveguide passage without termination 512 to generate “antinodes” of the waveguide standing wave 513 at intervals of half the guide wavelength. Plasma is generated by the microwave that is introduced into the plasma processing chamber 501 through a dielectric window 507 via slots 514 provided at positions between the antinodes of the standing wave at which the surface current becomes maximum.

When the electron density of the plasma exceeds the cutoff density and further exceeds the threshold density of generation of a surface wave mode, the microwave incident on the interface of the dielectric window 507 and the plasma cannot propagate in the plasma and it propagates as a surface wave 515 on the surface of the dielectric window 507. In the case of a microwave having a frequency of 2.45 GHz for example, the cutoff density is 7.5×10¹⁰ cm⁻³. In the case, for example, where use is made of a window made of quartz, the threshold density of generation of a surface wave mode is 3.4×10¹¹ cm⁻³. Surface waves 515 introduced through adjoining slots interfere with each other, whereby a surface standing wave 516 having antinodes at intervals of half the wavelength of the surface waves 515 is generated. Generation plasma having ultra high density and high electron temperature is created in the vicinity of the dielectric window 507 by the surface standing wave 516 existing locally near the surface of the dielectric window 507. The generation plasma 517 purely diffuses in the direction toward the substrate to be processed 502 to thereby be relaxed and creates plasma bulk 518 having high density and low electron temperature. The processing gas is excited by the high density plasma thus generated, so that it processes the surface of the substrate to be processed 502 set on the support member 503.

By making use of the microwave plasma processing apparatus as described above, high density, low electron temperature plasma having a high degree of uniformity can be generated. For example, high density, low electron temperature plasma having an electron density as high as or higher than 10¹¹ cm⁻³, an electron temperature as low as or lower than 1.5 eV and a plasma potential as low as or lower than 7 V can be generated at a microwave power equal to or higher than 1 kW with a high degree of uniformity with a variation of about ±5% in a large space with a diameter of 300 mm. Therefore, gas in an active state after sufficient reaction can be supplied to the substrate, and damage of the substrate surface caused by incident ions can be reduced. Thus, high quality, uniform, and high speed processing can be performed even at low temperatures.

However, in the case where the above described microwave plasma processing apparatus is used in a process in which a depositing material is produced, a deposit will adhere to a portion on the dielectric window for introducing microwave in which the surface wave electric field intensity is low or a portion in which the plasma density is low. After growth, the deposit will fall on the substrate as particles, which may sometimes cause a defect of a device.

### SUMMARY OF THE INVENTION

A principal object of the present invention is to provide a plasma processing apparatus in which deposition on the dielectric window that may produce particles is reduced.

A plasma processing apparatus according to the present invention comprises a vacuum chamber having a dielectric window, a microwave introduction portion that introduces a microwave into the vacuum chamber through the dielectric window and a radiofrequency wave electrode that superimposes a radiofrequency wave with a microwave introduced into the vacuum chamber.

According to the present invention, by applying a radiofrequency wave superimposed with the microwave for generating plasma, variations in the electron density distribution in the plasma generation portion are decreased, and generation of particles can be reduced by preventing a deposit from adhering on the surface of the dielectric window. In addition, controlling of the spatial distribution of the plasma in the vicinity of the substrate to be processed can be achieved as a secondary effect.

Further features of the present invention will become apparent from the following description of exemplary embodiments with reference to the attached drawings.

### BRIEF DESCRIPTION OF THE DRAWINGS

FIG. 1 shows a microwave plasma processing apparatus according to an embodiment of the present invention.

FIGS. 2A and 2B illustrate the positional relationship between a radiofrequency wave electrode and a slot in the apparatus shown in FIG. 1; FIG. 2A is a partial front view of the radiofrequency wave electrode, and FIG. 2B is a partial front view of a microwave introduction portion opposed to the radiofrequency wave electrode.

FIG. 3 shows an electron density distribution in a case where only the microwave introduction portion is used in the apparatus shown in FIG. 1.

FIG. 4 shows an electron density distribution in a case where both the microwave introduction portion and the radiofrequency wave introduction portion are used in the apparatus shown in FIG. 1.

FIG. 5 shows a microwave plasma processing apparatus according to a prior art.

FIGS. 6A and 6B illustrate the plasma generation principle in the apparatus shown in FIG. 5.

### DESCRIPTION OF THE EMBODIMENTS

A plasma processing apparatus according to a preferred embodiment of the present invention has a vacuum chamber partly composed of a dielectric window that can transmit microwaves, a support member provided in the vacuum chamber for supporting a substrate to be processed and an evacuation portion that exhausts the gas in the vacuum chamber. The plasma processing apparatus also has a gas introduction portion that introduces a processing gas into the vacuum chamber and a microwave introduction portion that introduces a microwave into the vacuum chamber through the dielectric window. Furthermore, the plasma processing apparatus is characterized in that it is provided with a radiofrequency wave electrode provided between the microwave introduction portion and the dielectric window and electrically insulated from the microwave introduction portion. The microwave introduction portion may be, for example, a slot antenna, and it is desirable that an opening is formed in the portion of the radiofrequency wave electrode opposite to the slot portion of the antenna.

A plasma processing apparatus according to another preferred embodiment of the present invention is characterized in that the aforementioned microwave introduction portion applies a radiofrequency wave having a frequency different from the frequency of the microwave in a superimposing manner.

In the above mentioned plasma processing apparatus, the frequency of the power applied to the radiofrequency wave electrode is preferably within the range of 0.03 to 300 MHz.

A plasma processing apparatus according to a preferred embodiment of the present invention is characterized in that the spatial distribution of the plasma is controlled by adjusting the power of the microwave supplied and the power or frequency of the radiofrequency wave.

A plasma processing apparatus according to a preferred embodiment of the present invention is characterized in that the spatial distribution of the plasma is changed with time by changing the power of the microwave supplied and the power or frequency of the radiofrequency wave with time.

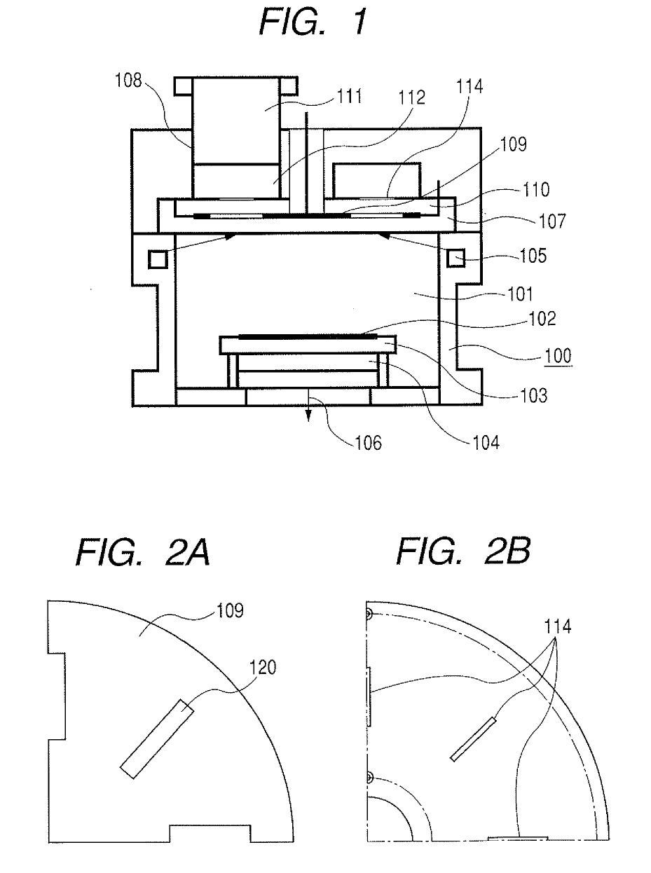

A microwave plasma processing apparatus according to a preferred embodiment of the present invention will be described with reference to FIG. 1. In FIG. 1, the microwave plasma processing apparatus has a vacuum chamber 100, a plasma processing chamber 101, a substrate to be processed 102, a support member 103 for the substrate to be processed 102, a substrate temperature controlling portion 104, a plasma processing gas introduction portion 105 provided in the vicinity of the plasma processing chamber 101. FIG. 1 also shows exhaust gas 106 and a dielectric window 107 that separates the plasma processing chamber 101 from the atmosphere. On the atmosphere side, there is a microwave introduction portion 108 for introducing a microwave into the plasma processing chamber 101 through the dielectric window 107. The microwave introduction portion 108 may be, for example, a circular waveguide without termination. FIG. 1 further shows a radiofrequency wave electrode 109, an insulating member 110 that provides insulation between the microwave introduction portion 108 and the radiofrequency wave electrode 109 and slots 114 formed in a radial portion of the microwave introduction portion 108. As shown in FIGS. 2A and 2B, opening portions 120 are provided in the portions of the radiofrequency wave electrode 109 that are opposed to the regions of the slots 114 when the slots are placed over it. FIG. 1 further shows an introducing E-branch portion that introduces a microwave into the circular waveguide 108 and a circular waveguide passage 112.

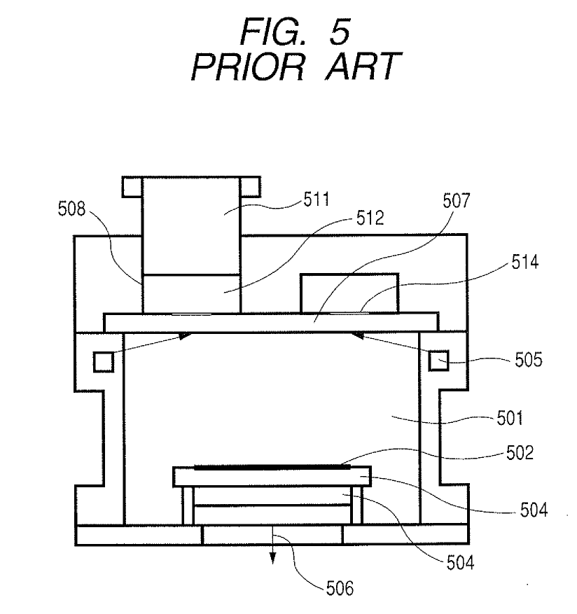

As per the above, in the apparatus illustrated in FIG. 1, the radiofrequency wave electrode 109 and the insulating member 110 are added to the prior art apparatus shown in FIG. 5.

As an alternative configuration according to the present invention, a radiofrequency wave may be introduced directly into the microwave introduction portion 108 without using the radiofrequency wave electrode 109 and the insulating member 110.

Plasma processing is performed in the following manner. In the state in which a substrate to be processed 102 is set on the supporting member 103, the interior of the plasma processing chamber 101 is evacuated through an exhaust system (not shown). Subsequently, processing gas is introduced into the plasma processing chamber 101 at a predetermined flow rate through the gas introduction portion 105 provided in the vicinity of the plasma processing chamber 101. Then a conductance valve (not shown) provided in the exhaust system (not shown) is adjusted to keep the interior of the plasma processing chamber 101 at a predetermined pressure.

A desired amount of electric power is supplied into the plasma processing chamber 101 from a microwave power source (not shown) through the microwave introduction portion 108, whereby an initial high density plasma is generated in the vicinity of the dielectric window 107.

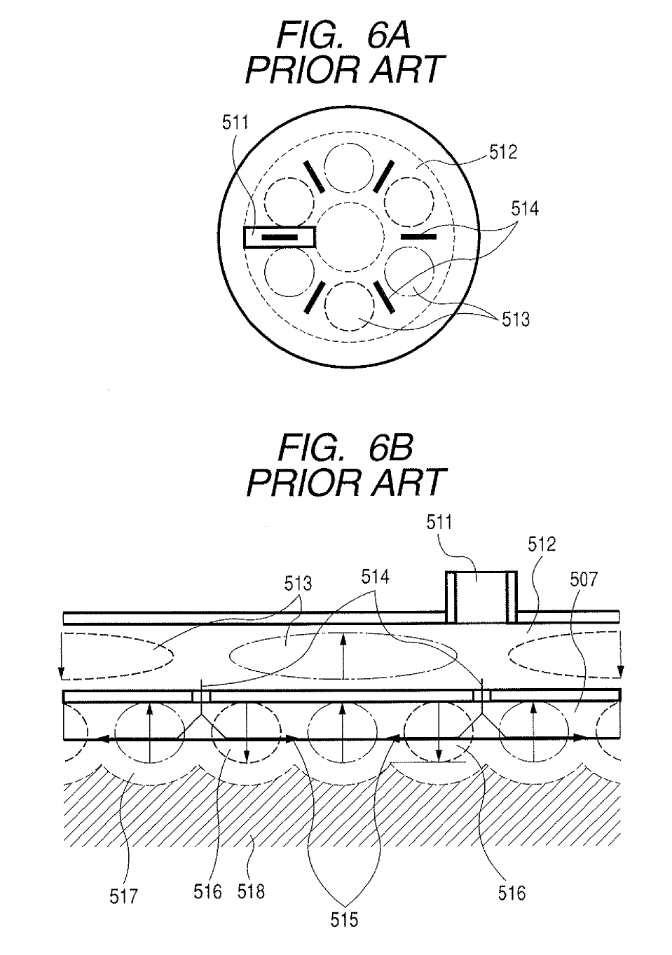

When the electron density of the initial high density plasma has exceeded the cutoff density or, more specifically, the threshold density of generation of surface wave mode, the microwave incident on the interface of the dielectric window 107 and the initial high density plasma cannot propagate into the initial high density plasma. Here, for example, in the case of a microwave having a frequency of 2.45 GHz, the cutoff density is 7.5×10¹⁰ cm⁻³. In the case, for example, where a window made of quartz is used, the threshold density of generation of surface wave mode is 3.4×10¹¹ cm⁻³. Microwaves that cannot propagate into the initial high density plasma propagate as surface waves 515 (FIGS. 6A and 6B) on the interface of the dielectric window 107 and the initial high density plasma. Then, the surface waves interfere with each other to display an electric field intensity distribution that is determined by a specific surface wave mode. In addition, generation plasma 517 (FIGS. 6A and 6B) having a very high density is created in the vicinity of the dielectric window 107 by the surface wave electric field locally existing on the surface of the dielectric window 107. The plasma thus generated creates, by diffusion and relaxation, a high density, low electron temperature plasma bulk 518 (FIGS. 6A and 6B). The processing gas is excited and decomposed by the high density, low electron temperature plasma to thereby be made active, so that the processing gas processes the surface of the substrate to be processed 102 placed on the support member 103.

In the above process, by applying radiofrequency wave power to the radiofrequency wave electrode 109 simultaneously with the introduction of the microwave power, plasma is generated also in portions in which the surface wave electric field is weak. In addition, a self bias is generated on the surface of the dielectric window 107, and ions are accelerated by sheath electric field in directions from the plasma toward the surface of the dielectric window 107, whereby adhesion of a deposit on the surface of the dielectric window 107 is controlled. Thus, generation of particles mainly produced by a deposit on the surface of the dielectric window 107 can be reduced.

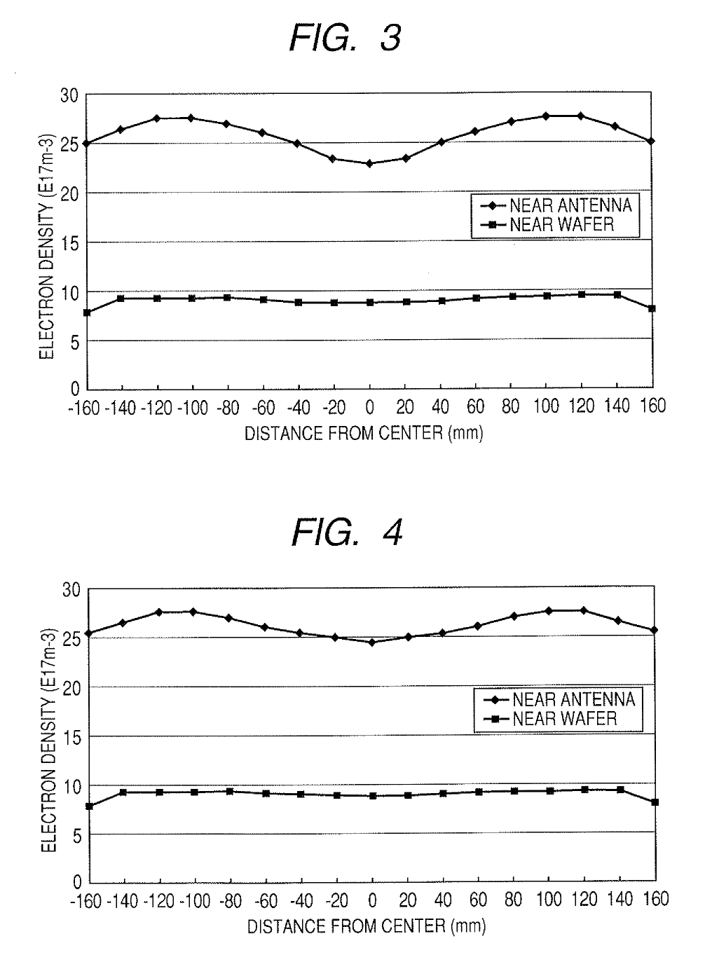

FIG. 3 shows electron density distributions in the plasma generation portion (represented by diamond dots in FIG. 3) and in the vicinity of the substrate to be processed (represented by square dots in FIG. 3) in a case where only the microwave introduction portion 108 was used, the gas used was He at a pressure of 0.5 Torr and discharge was performed at a microwave power of 3 kW. FIG. 4 shows electron density distributions in the plasma generation portion and in the vicinity of the substrate to be processed in a case where the radiofrequency wave electrode 109 was additionally used, where the gas used was He at a pressure of 0.5 Torr and discharge was performed at a microwave power of 3 kW with a radiofrequency wave having a frequency of 13.56 MHz and a power of 1.2 kW. In the case shown in FIG. 3, strong ring-shaped plasma was generated in the vicinity of a slot and an influence of the distribution in the plasma generation portion was observed also in the vicinity of the substrate to be processed to some extent, and the distribution in the vicinity of the substrate to be processed had a variation of about ±4%. On the other hand, in the case of FIG. 4, plasma was generated also in the portion where the surface wave electric field was weak and the plasma density was low in the case of FIG. 3, and the distribution in the vicinity of the substrate to be processed had improved uniformity with a variation of about ±2.4%.

As per the above, by applying a radiofrequency wave superimposed with the microwave for generating plasma, variations in the electron density distribution in the plasma generation portion are decreased, and generation of particles can be reduced by preventing a deposit from adhering on the surface of the dielectric window. In addition, controlling of the spatial distribution of the plasma in the vicinity of the substrate to be processed can be achieved as a secondary effect.

The foregoing description has been directed to a case where a radiofrequency wave electrode that is electrically insulated from the microwave introduction portion is provided between the microwave introduction portion and the dielectric window. However, the same effects can be obtained in cases where a radiofrequency wave having a frequency different from the frequency of the microwave is applied on the microwave introduction portion in a superimposing manner.

It is desirable in the microwave plasma processing apparatus according to the present invention that an opening be provided in the portion of the radiofrequency wave electrode used therein that faces the microwave emitting region such as a slot so that introduction of the microwave is not prevented.

It is desirable in the microwave plasma processing apparatus according to the present invention that an insulating member be provided between the radiofrequency wave electrode used therein and the microwave introduction portion so that electric insulation from the microwave introduction portion is ensured.

Appropriate frequencies of the radiofrequency wave used in the microwave plasma processing apparatus according to the present invention are 0.03 to 300 MHz.

The materials that can be used to make the dielectric window used in the microwave plasma processing apparatus according to the present invention are materials having sufficient mechanical strength and a dielectric defect that is small enough to achieve sufficient microwave transmissivity. The most suitable materials include quartz, alumina (or sapphire), aluminum nitride and carbon fluorine polymer (or Teflon: registered trademark).

The microwave introduction portion used in the present invention has a hollow structure, and it may be a circular waveguide multi-slot antenna, an antenna of a cavity resonator type, a coaxially coupled applicator, a coaxial waveguide introduction flat plate antenna and a patch antenna.

The present invention can be preferably applied to an apparatus in which a microwave emitting portion such as a slot serving as a microwave introduction portion is relatively localized, especially to an apparatus in which use is made of a microwave introduction portion having a small number of slots such as a slotted circular waveguide.

Electrically conductive materials can be used to make the slotted circular waveguide without termination as an example of the microwave introduction portion used in the microwave plasma processing apparatus according to the present invention. However, to make the microwave transmission loss as small as possible, a material like SUS plated with a material having a high conductivity such as Al, Cu or Ag/Cu is most suitable. The orientation of the inlet opening of the slotted circular waveguide without termination may be parallel to the H-plane, perpendicular to the H-plane, directed in the tangential direction of the propagation space, or arranged to separate into right and left directions of the propagation space as long as the microwave can be introduced efficiently into the microwave propagation space in the slotted circular waveguide without termination.

In the present invention, a magnetic field generator may be used to allow processing at lower pressures. In this case, a magnetic field that is perpendicular to the electric field generated in the width direction of the slots may be applied. As the magnetic field generator, a permanent magnet can be used as well as a coil. When a coil is used, a cooling apparatus such as a water-cooling or air-cooling mechanism may additionally be used to prevent overheating.

The surface of the substrate may be irradiated with ultraviolet light. To this end, any light source that emits light that is absorbed by the substrate to be processed or the gas adhering on the substrate may be used. The suitable light sources include an excimer laser, an excimer lamp, a rare gas resonance line lamp and a low pressure mercury lamp.

In the microwave plasma processing method of the present invention, the pressure in the plasma processing chamber is preferably in the range of 0.1 mTorr to 10 Torr, more preferably in the range of 10 mTorr to 3 Torr.

According to the plasma processing apparatus and method of the present invention, various deposited film can be formed efficiently by selecting the gas used appropriately. Deposited films to be formed include insulator films made of materials such as Si₃N₄, SiO₂, SiOF, Ta₂O₅, TiO₂, TiN, Al₂O₃, AlN, MgF₂, HfSiO, HfSiON, HfAlO and HfAlON. In addition, semiconductor films made of materials such as a-Si, poly-Si, SiC, SiGe and GaAs, conductive films made of materials such as Al, W, Mo, Ti and Ta and carbon films are also included.

The substrate to be processed by the plasma processing apparatus according to the present invention may be a semiconductor substrate, a conductive substrate or an electrically insulative substrate.

The materials of the conductive substrates include Fe, Ni, Cr, Al, Mo, Au, Nb, Ta, V, Ti, Pt and Pb and alloys of these materials such as brass and stainless steel. The materials of the insulative substrates include quartz of SiO₂ system, various glasses and inorganic materials such as Si₃N₄, NaCl, KCl, LiF, CaF₂, BaF₂, Al₂O₃, AlN and MgO. The insulative substrates further include films or sheets made of organic materials such as polyethylene, polyester, polycarbonate, cellulose acetate, polypropylene, polyvinyl chloride, polyvinylidene chloride, polystyrene, polyamide and polyimide.

The most appropriate orientation of the gas introduction portion used in the plasma processing apparatus according to the present invention is such a direction that causes the gas to flow through the plasma region generated in the vicinity of the dielectric window, then be sufficiently supplied to the region near the center and then flow on the surface of the substrate from its center toward its periphery. Therefore, it is optimum for the gas introduction portion to be adapted to blow the gas toward the dielectric window.

Generally known gases can be used in forming a thin film on the substrate by CVD.

In the case where a thin film of a silicon-based semiconductor such as a-Si, poly-Si or SiC is to be formed, the source material of the gas containing Si atoms to be introduced into the plasma processing chamber through the processing gas introduction portion is a compound that is in the gas state at normal temperature and normal pressure or can be easily vaporized. Examples of such a compound include inorganic silanes such as SiH₄ and Si₂H₆ and organic silanes such as tetraethylsilane (TES), tetramethylsilane (TMS), dimethylsilane (DMS), dimethylfluorosilane (DMDFS) and dimethyldichlorosilane (DMDCS). Other examples of such a compound include silane halides such as SiF₄, Si₂F₆, Si₃F₈, SiHF₃, SiH₂F₂, SiCl₄, Si₂Cl₆, SiHCl₃, SiH₂Cl₂, SiH₃Cl and SiCl₂F₂. In this case, examples of the additive gas or carrier gas that may be mixed with the aforementioned Si source material gas so as to be introduced include H₂, He, Ne, Ar, Kr, Xe and Rn.

In the case where a thin film of a Si-compound such as SI₃N₄ or SiO₂ is to be formed, the source material containing Si atoms to be introduced through the processing gas introduction portion may be a compound that is in the gas state at normal temperature and normal pressure or can be easily vaporized. Examples of such a compound include inorganic silanes such as SiH₄ and Si₂H₆. Other examples include tetraethoxysilane (TEOS), tetramethoxysilane (TMOS), octamethylcyclotetrasilane (OMCTS), dimethyldifluorosilane (DMDFS) and dimethyldichlorosilane (DMDCS). Other examples of such a compound include silane halides such as SiF₄, Si₂F₆, Si₃F₈, SiHF₃, SiH₂F₂, SiCl₄, Si₂Cl₆, SiHCl₃, SiH₂Cl₂, SiH₃Cl and SiCl₂F₂. In this case, examples of the nitrogen source material gas or oxygen source material gas that may be introduced simultaneously with the aforementioned material include N₂, NH₃, N₂H₄, hexamethyldisilazane (HMDS), O₂, O₃, H₂O, NO, N₂O and NO₂.

In the case where a thin film of a metal such as Al, W, Mo, Ti or Ta is to be formed, the source material containing metal atoms to be introduced through the processing gas introduction portion may be, for example, an organometallic compound or a metal halide as listed below. Examples of the organometallic compound include trimethylaluminum (TMAl), triethylaluminum (TEAl), triisobutylaluminum (TIBAl), dimethylaluminum hydride (DMAlH), tungsten carbonyl (W(CO)₆). Other examples include molybdenum carbonyl (Mo (CO)₆), trimethylgallium (TMGa), triethylgallium (TEGa), tetraisopropoxytitanium (TIPOTi) and pentaethoxytantalum (PEOTa). Examples of the metal halide include AlCl₃, WF₆, TiCl₃ and TaCl₅. In this case, examples of the additive gas or carrier gas that may be mixed with the aforementioned Si source material gas to be introduced include H₂, He, Ne, Ar, Kr, Xe and Rn.

In the case where a thin film of a metal compound such as Al₂O₃, AlN, Ta₂O₅, TiO₂, TiN or WO₃ is to be formed, the source material containing metal atoms to be introduced through the processing gas introduction portion may be, for example, an organometallic compound or a metal halide as listed below. Examples of the organometallic compound include trimethylaluminum (TMAl), triethylaluminum (TEAl), triisobutylaluminum (TIBAl), dimethylaluminum hydride (DMAlH), tungsten carbonyl (W(CO)₆). Other examples include molybdenum carbonyl (Mo(CO)₆), trimethylgallium (TMGa), triethylgallium (TEGa), tetraisopropoxytitanium (TIPOTi) and pentaethoxytantalum (PEOTa). Examples of the metal halide include AlCl₃, WF₆, TiCl₃ and TaCl₅. In this case, examples of the oxygen source material gas or nitrogen source material gas that may be introduced simultaneously with the aforementioned material include O₂, O₃, H₂O, NO, N₂O, NO₂, N₂, NH₃, N₂H₄ and hexamethyldisilazane (HMDS).

In the case where a thin film of a carbon-based material such as graphite, carbon nanotube (CNT), diamond-like carbon (DLC) or diamond is to be formed, the source material to be introduced through the processing gas introduction portion 105 may be any material containing carbon. Examples of suitable materials include saturated hydrocarbons such as CH₄, C₂H₆ and C₃H₈, unsaturated hydrocarbons such as C₂H₄, C₃H₆, C₂H₂ and C₃H₄, aromatic hydrocarbons such as C₆H₆ and alcohols such as C₃OH and C₂H₅OH. Other examples of suitable materials include ketones such as (CH₃)₂CO, aldehydes such as CH₃CHO and carboxylic acids such as HCOOH and CH₃COOH.

In the case where the surface of the substrate is to be etched, examples of the etching gas to be introduced through the processing gas introduction portion 105 include F₂, CF₄, CH₂F₂, C₂F₆, C₃F₈, C₄F₈, CF₂Cl₂, SF₆, NF₃, Cl₂, CCl₄, CH₂Cl₂, and C₂Cl₆. In the case where organic components such as photoresist on the surface of the substrate is to be removed by ashing, example of the ashing gas to be introduced through the processing gas introduction portion 105 include O₂, O₃, H₂O, NO, N₂O, NO₂, N₂ and H₂.

In the case where the microwave plasma processing apparatus or processing method according to the present invention is applied to modify a surface, various processing can be performed by appropriately selecting the gas used. For example, the substrate or the surface layer thereof may be made of Si, Al, Ti, Zn or Ta, and oxidizing process or nitriding process or B, As or P doping process can be performed on the substrate or the surface layer. The deposition or film forming technique used in the present invention can also be applied to cleaning process. For example, the technique may be used to remove an oxide, a organic matter or a heavy metal. The technique may also be used to remove organic components such as photoresist on the substrate surface by ashing.

In the case a surface oxidizing process is to be applied on the substrate, examples of the oxidizing gas to be introduced through the processing gas introduction portion include O₂, O₃, H₂O, NO, N₂O and NO₂. In the case a surface nitriding process is to be applied on the substrate, examples of the nitriding gas to be introduced through the processing gas introduction portion 105 include N₂, NH₃, N₂H₄ and hexamethyldisilazane (HMDS).

In the case where organic matters on the substrate surface are to be removed by cleaning or ashing, examples of the cleaning/ashing gas to be introduced through the gas introduction portion include O₂, O₃, H₂O, NO, N₂O, NO₂, N₂ and H₂. In the case where inorganic matters on the substrate surface is to be removed by cleaning, examples of the cleaning gas to be introduced through the plasma generation gas introduction portion include F₂, CF₄, CH₂F₂, C₂F₆, C₄F₈, CF₂Cl₂, SF₆ and NF₃.

In the following, the microwave plasma processing apparatus according to the present invention will be described more specifically based on examples, but the present invention is not limited to these examples.

### EXAMPLE 1

Ashing of photoresist was performed using the microwave plasma processing apparatus shown in FIG. 1.

The substrate 102 used was a silicon (Si) substrate (with a diameter φ of 300 mm) in which etching of interlaminar SiO₂ film has been just performed and via holes have been just formed.

First, the Si substrate 102 was set on the support member 103, thereafter the Si substrate 102 was heated to 250° C. by a heater 104, and the interior of the plasma processing chamber 101 was evacuated through the evacuation system (not shown), whereby the pressure in the plasma processing chamber 101 was reduced to 10⁻⁴ Torr. Then, oxygen gas was introduced into the plasma processing chamber 101 at a flow rate of 2 slm (standard liter per minute) through the plasma processing gas introduction portion 105. Then, the conductance valve (not shown) provided in the evacuation system (not shown) was adjusted to keep the pressure in the plasma processing chamber 101 at 1.5 Torr. An electric power of 2.5 kW was supplied into the plasma processing chamber 101 by a microwave power source of 2.45 GHz through the slotted circular waveguide without termination 108 and an electric power of 1.2 kW was supplied into the plasma processing chamber 101 simultaneously by a radiofrequency wave power source of 13.56 MHz through the radiofrequency wave electrode 109. In this way, plasma was generated in the interior of the plasma processing chamber 101. In this process, the oxygen gas introduced through the plasma processing gas introduction portion 105 was transformed into oxygen atoms through excitation, decomposition and reaction in the plasma processing chamber 101, and the oxygen atoms were transferred toward the silicon substrate 102 to oxidize the photoresist on the substrate 102. Thus, the photoresist was vaporized and removed.

After completion of the ashing, evaluation was made as to the degree of uniformity in the ashing speed, the charge density on the substrate surface and particle generation after 1000 substrates have been processed.

The degree of uniformity in the ashing speed was very excellent with a variation of the ashing speed being ±2.4% (6.1 ∥m/min), the surface charge density was sufficiently low (0.6×10¹¹ cm⁻²), and particle generation was of no matter.

### EXAMPLE 2

Ashing of photoresist was performed using the microwave plasma processing apparatus shown in FIG. 1.

The substrate 102 used was a silicon (Si) substrate (with a diameter φ of 300 mm) in which etching of interlaminar SiO₂ film has been just performed and via holes have been just formed.

First, the Si substrate 102 was set on the support member 103, thereafter the Si substrate 102 was heated to 250° C. by a heater 104, and the interior of the plasma processing chamber 101 was evacuated through the evacuation system (not shown), whereby the pressure in the plasma processing chamber 101 was reduced to 10⁻⁵ Torr. Then, oxygen gas was introduced into the plasma processing chamber 101 at a flow rate of 2 slm (standard liter per minute) through the plasma processing gas introduction portion 105. Then, the conductance valve (not shown) provided in the evacuation system (not shown) was adjusted to keep the pressure in the plasma processing chamber 101 at 2 Torr. An electric power of 2.5 kW was supplied into the plasma processing chamber 101 by a microwave power source of 2.45 GHz through the slotted circular waveguide without termination 108 and an electric power of 1.2 kW was supplied into the plasma processing chamber 101 simultaneously by a radiofrequency wave power source of 13.56 MHz through the radiofrequency wave electrode 109. In this way, plasma was generated in the interior of the plasma processing chamber 101. In this process, the oxygen gas introduced through the plasma processing gas introduction portion 105 was transformed into oxygen atoms through excitation, decomposition and reaction in the plasma processing chamber 101, and the oxygen atoms were transferred toward the silicon substrate 102 to oxidize the photoresist on the substrate 102. Thus, the photoresist was vaporized and removed.

After completion of the ashing, evaluation was made as to the degree of uniformity in the ashing speed, the charge density on the substrate surface and particle generation after 1000 substrates have been processed.

The degree of uniformity in the ashing speed was very excellent a variation of the ashing speed being ±3.1% (7.9 μm/min), the surface charge density was sufficiently low (1.0×10¹¹ cm⁻²), and particle generation was of no matter.

### EXAMPLE 3

Nitriding of the surface of an ultrathin oxide film was performed using the microwave plasma processing apparatus shown in FIG. 1. The substrate 102 used was a silicon (Si) substrate (with a diameter φ of 200 mm) having a surficial oxide film of a thickness of 16A.

First, the Si substrate 102 was set on the support member 103, thereafter the Si substrate 102 was heated to 150° C. by a heater 104, and the interior of the plasma processing chamber 101 was evacuated through the evacuation system (not shown), whereby the pressure in the plasma processing chamber 101 was reduced to 10⁻³ Torr. Then, nitrogen gas and helium gas were introduced into the plasma processing chamber 101 at flow rates of 50 sccm (standard cc per minute) and 450 sccm respectively, through the plasma processing gas introduction portion 105. Then, the conductance valve (not shown) provided in the evacuation system (not shown) was adjusted to keep the pressure in the plasma processing chamber 101 at 0.2 Torr. An electric power of 1.5 kW was supplied into the plasma processing chamber 101 by a microwave power source of 2.45 GHz through the slotted circular waveguide without termination 108 and an electric power of 1.2 kW was supplied into the plasma processing chamber 101 simultaneously by a radiofrequency wave power source of 13.56 MHz through the radiofrequency wave electrode 109. In this way, plasma was generated in the interior of the plasma processing chamber 101. In this process, the nitrogen gas introduced through the plasma processing gas introduction portion 105 was transformed into nitrogen ions and atoms through excitation, decomposition and reaction in the plasma processing chamber 101, and the ions and atoms were transferred toward the silicon substrate 102 to nitride the surface of the oxide film on the substrate 102.

After completion of the nitriding process, evaluation was made as to the degree of uniformity of the nitriding speed, the charge density on the substrate surface and particle generation after 1000 substrates have been processed.

The degree of uniformity in the nitriding speed was very excellent with a variation of the nitriding speed being ±1.5%, the surface charge density was sufficiently low (0.9×10¹¹ cm⁻²), and particle generation was of no matter.

### EXAMPLE 4

Direct nitriding was performed on a silicon substrate using the microwave plasma processing apparatus shown in FIG. 1. The substrate 102 used was a bare silicon (Si) substrate (with a diameter φ of 200 mm).

First, the Si substrate 102 was set on the support member 103, thereafter the Si substrate 102 was heated to 150° C. by a heater 104, and the interior of the plasma processing chamber 101 was evacuated through the evacuation system (not shown), whereby the pressure in the plasma processing chamber 101 was reduced to 10⁻³ Torr. Then, nitrogen gas was introduced into the plasma processing chamber 101 at a flow rate of 500 sccm through the plasma processing gas introduction portion 105. Then, the conductance valve (not shown) provided in the evacuation system (not shown) was adjusted to keep the pressure in the plasma processing chamber 101 at 0.1 Torr. An electric power of 1.5 kW was supplied into the plasma processing chamber 101 by a microwave power source of 2.45 GHz through the slotted circular waveguide without termination 108 and an electric power of 1.2 kW was supplied into the plasma processing chamber 101 simultaneously by a radiofrequency wave power source of 13.56 MHz through the radiofrequency wave electrode 109. In this way, plasma was generated in the interior of the plasma processing chamber 101. In this process, the nitrogen gas introduced through the plasma processing gas introduction portion 105 was transformed into nitrogen ions and atoms through excitation, decomposition and reaction in the plasma processing chamber 101, and the ions and atoms were transferred toward the silicon substrate 102 to directly nitride the surface of the substrate 102.

After completion of the nitriding process, evaluation was made as to the degree of uniformity of the nitriding speed, the charge density on the substrate surface and particle generation after 1000 substrates have been processed.

The degree of uniformity in the nitriding speed was very excellent with a variation of the nitriding speed being ±1.1%, the surface charge density was sufficiently low (1.7×10¹¹ cm⁻²), and particle generation was of no matter.

### EXAMPLE 5

Formation of a silicon nitride film for protecting semiconductor device was performed using the microwave plasma processing apparatus shown in FIG. 1. The substrate 102 used was a P-type single crystal silicon substrate with an interlaminar SiO₂ film having an Al wiring pattern (with line-and-space of 0.5 μm) formed thereon, the silicon substrate having a diameter φ of 300 mm, plane orientation of <1 0 0> and resistivity of 10 Ωcm.

First, the Silicon substrate 102 was set on the support member 103, and thereafter the interior of the plasma processing chamber 101 was evacuated through the evacuation system (not shown), whereby the pressure in the plasma processing chamber 101 was reduced to 10⁻⁷ Torr. Then, power was supplied to a heater 104 to heat the silicon substrate 102 to 300° C., and the temperature of the substrate was kept at that temperature. Then, nitrogen gas and monosilane gas were introduced into the plasma processing chamber 101 at flow rates of 600 sccm and 200 sccm respectively, through the plasma processing gas introduction portion 105. Thereafter, the conductance valve (not shown) provided in the evacuation system (not shown) was adjusted to keep the pressure in the plasma processing chamber 101 at 20 mTorr. Then, an electric power of 3.0 kW was supplied into the plasma processing chamber 101 by a microwave power source (not shown) of 2.45 GHz and an electric power of 1.2 kW was supplied into the plasma processing chamber 101 simultaneously by a radiofrequency wave power source of 13.56 MHz, through the slotted circular waveguide without termination 108. In this way, plasma was generated in the interior of the plasma processing chamber 101. In this process, the nitrogen gas introduced through the plasma processing gas introduction portion 105 was transformed into nitrogen atoms through excitation and decomposition in the plasma processing chamber 101, and the atoms were transferred toward the silicon substrate 102 to react with the monosilane gas. As a result, a silicon nitride film with a thickness of 1.0 μm was deposited on the silicon substrate 102.

After the film has been deposited, evaluation was made as to the degree of uniformity in the deposition rate, characteristics of the film such as stress and particle generation after 1000 substrates have been processed. In evaluating the stress, a difference in the warpage of the substrate between before and after film deposition was determined by measurement using a laser interferometer Zygo (trade name).

The degree of uniformity of the deposition rate of the silicon nitride film thus obtained was very excellent with a variation in the deposition rate being ±2.6% (530 nm/min). It was also found that the quality of the film formed was a very good with the stress being 0.9×10⁹ dyne cm⁻² (compression), the leak current being 1.1×10⁻¹⁰ A·cm⁻² and the dielectric voltage being 10.7 MV/cm. In addition, particle generation was of no matter.

### EXAMPLE 6

A silicon oxide film and a silicon nitride film as anti-reflection films for a plastic lens were formed using the microwave plasma processing apparatus shown in FIG. 1. The substrate 102 used was a plastic convex lens with a diameter of 50 mm.

The lens 102 was set on the support member 103, and thereafter the interior of the plasma processing chamber 101 was evacuated through the evacuation system (not shown), whereby the pressure in the plasma processing chamber 101 was reduced to 10⁻⁷ Torr. Then, nitrogen gas and monosilane gas were introduced into the plasma processing chamber 101 at flow rates of 150 sccm and 70 sccm respectively, through the plasma processing gas introduction portion 105. Thereafter, the conductance valve (not shown) provided in the evacuation system (not shown) was adjusted to keep the pressure in the plasma processing chamber 101 at 5 mTorr. Then, an electric power of 3.0 kW was supplied into the plasma processing chamber 101 by a microwave power source (not shown) of 2.45 GHz and an electric power of 1.2 kW was supplied into the plasma processing chamber 101 simultaneously by a radiofrequency wave power source of 13.56 MHz, through the slotted circular waveguide without termination 108. In this way, plasma was generated in the interior of the plasma processing chamber 101. In this process, the nitrogen gas introduced through the plasma processing gas introduction portion 105 was transformed into active species such as nitrogen atoms through excitation and decomposition in the plasma processing chamber 101, and they were transferred toward the lens 102 to react with the monosilane gas. As a result, a silicon nitride film with a thickness of 20 nm was deposited on the lens 102.

After that, oxygen gas and monosilane gas were introduced into the plasma processing chamber 101 at flow rates of 200 sccm and 100 sccm respectively, through the plasma processing gas introduction portion 105. Then, the conductance valve (not shown) provided in the evacuation system (not shown) was adjusted to keep the pressure in the plasma processing chamber 101 at 2 mTorr. Then, an electric power of 2.0 kW was supplied into the plasma processing chamber 101 by a microwave power source (not shown) of 2.45 GHz and an electric power of 1.2 kW was supplied into the plasma processing chamber 101 simultaneously by a radiofrequency wave power source of 13.56 MHz, through the slotted circular waveguide without termination 108. In this way, plasma was generated in the interior of the plasma processing chamber 101. In this process, the oxygen gas introduced through the plasma processing gas introduction portion 105 was transformed into active species such as oxygen atoms through excitation and decomposition in the plasma processing chamber 101, and they were transferred toward the lens 102 to react with the monosilane gas. As a result, a silicon oxide film with a thickness of 85 nm was deposited on the lens 102.

After the films have been deposited, evaluation was made as to the degree of uniformity in the deposition rate, the reflection characteristics of the film and particle generation after 1000 lenses have been processed.

The degree of uniformity in the deposition rate of the silicon nitride film and silicon oxide film obtained was very excellent with a variation in the deposition rate being ±2.7% (380 nm/min) and ±2.9% (410 nm/min) respectively. It was also found that the optical characteristics of the film formed were a very good with the reflectance near a wavelength of 500 nm being 0.14%. In addition, particle generation was of no matter.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2007-012902, filed Jan. 23, 2007, which is hereby incorporated by reference herein in its entirety.

What is claimed is:

1. A plasma processing apparatus comprising:
a vacuum chamber having a dielectric window;
a microwave introduction portion that introduces a microwave into the vacuum chamber through the dielectric window; and
a radiofrequency wave electrode that superimposes a radiofrequency wave with the microwave introduced into the vacuum chamber.

2. A plasma processing apparatus according to claim 1, wherein the radiofrequency wave electrode is provided between the microwave introduction portion and the dielectric window and electrically insulated from the microwave introduction portion.

3. A plasma processing apparatus according to claim 2, wherein the microwave introduction portion comprises a slot antenna, and an opening portion is provided in a portion of the radiofrequency wave electrode that is opposite to a slot portion of the antenna.

4. A plasma processing apparatus comprising:
a vacuum chamber having a dielectric window; and
a microwave introduction portion that introduces a microwave into the vacuum chamber through the dielectric window,
wherein the microwave introduction portion applies a radiofrequency wave having a frequency different from the frequency of the microwave into the vacuum chamber with the microwave.

5. A plasma processing apparatus according to claim 1, wherein the frequency of the radiofrequency wave is within the range of 0.03 to 300 MHz.

6. A plasma processing apparatus according to claim 1, wherein power of the microwave is changed with time.

7. A plasma processing apparatus according to claim 1, wherein at least one of power or frequency of the radiofrequency wave is changed with time.
